(19) United States
(12) Patent Application Publication
(10) Pub. No.: US 2011/0023942 A1
(43) Pub. Date: Feb. 3, 2011

(54) PHOTOVOLTAIC MODULE HAVING IMPROVED CORROSION RESISTANCE AND METHOD OF PRODUCING SAME

(76) Inventors: Thorsten Soegding, Landau (DE); Ulf Dahlmann, Gau-Odernheim (DE); Ralf Eiden, Mainz (DE); Kurt Nattermann, Ockenheim (DE); Ingo Schwirtlich, Miltenberg (DE); Uwe Fliedner, Kleinostheim (DE); Fritz Heyer, Alzenau (DE); Ralf Gueldner, Aschaffenburg (DE)

Correspondence Address: MICHAEL J. STRIKER, 103 EAST NECK ROAD, HUNTINGTON, NY, 11743, US

(21) Appl. No.: 12/844,882

(22) Filed: Jul. 28, 2010

(30) Foreign Application Priority Data
Jul. 30, 2009 (DE) 10 2009 028 118.5

(51) Int. Cl. H01L 31/048

(52) U.S. Cl. 136/251

(57) ABSTRACT

The improved photovoltaic module contains a solar cell made of metallic silicon, which is embedded in at least one embedding material, and a corrosion inhibitor. Preferably the corrosion inhibitor is an organic compound, which has at least one nitrogen atom. As a result, the photovoltaic module according to the present invention has an extended service life, since it withstands corrosive influences.

### CROSS-REFERENCE

The invention described and claimed herein below is also described in German Patent Application 10 200 118.5, filed Jul. 30, 2009 in Germany. The aforesaid German Patent Application, whose subject matter is incorporated herein by reference thereto, provides the basis for a claim of priority of invention for the invention claimed herein below under 35 U.S.C. 119 (a)-(d).

### BACKGROUND

1. The Field of the Invention

The present invention relates to photovoltaic modules having improved corrosion resistance comprising metallic silicon and at least one embedding material as well as a method for producing the same.

2. The Description of the Related Art

The development of photovoltaic modules has already been strongly promoted for some years. Now different products with different features and materials are available on the market. The so-called cell substantially consisting of metallic silicon is a common feature of all these products. The cell is enclosed within an encapsulation to protect against influences from its surroundings. “Encapsulation” means all materials which enclose the solar cell. Usually this means a front pane and a back cover, for example a back pane or a back foil, as well as the so-called embedding material. Normally, the embedding material is a plastic foil, in particular ethylene vinyl acetate (EVA). But the solar cells can also be laminated or cast into other transparent materials.

Different embedding materials, and in particular EVA, are degraded by UV radiation, air humidity from the environment and agency of temperature, wherein degradation products may be produced which partly have corrosive properties. These substances may move in the whole photovoltaic module by diffusion and damage the metallic components of the photovoltaic module over long periods of time. Metallic components are in particular so-called connectors, but also include the metallization and all other elements consisting of metal. The chemical corrosion of the metallic components ultimately leads to performance loss in the module during its operation, which can be observed by the operator of the photovoltaic facility as a decreasing yield.

The phenomenon of metal corrosion has been known for years. Many efforts have been taken to prevent the changes of the metallic material. E.g., the following measures have been taken to reduce corrosion:
suitable selection of material,
favorable construction measures,
application of metallic protective coatings (e.g. zinc, nickel or chromium),
phosphating of metals,
enameling and
electrochemical methods.

Unfortunately, these methods can only be used to a limited extend for photovoltaic modules, because in the construction of the photovoltaic module transparency and the refractive properties of its materials, which are adjusted to one another, are very important.

Photovoltaic modules are designed for use for decades. During this time period they are subjected to extreme fluctuations of environmental conditions.

FIG. 1 shows an example of a common structure of a photovoltaic module. Usually the front cover 1 of the photovoltaic module consists of a glass plate and is often laminated with an embedding foil 3 and the cell 4. The back side of the photovoltaic module is often strengthened with a back cover 2. The back cover 2 may also be a glass plate. Also back foils may be considered. Since transparency is not important with respect to the back cover, the material selection for it is hardly limited.

For the embedding foil often EVA (ethylene vinyl acetate) is used. If the embedding foil is stressed by e.g. UV radiation, humidity or temperature, in the course of time it will release degradation products into the surrounding layers. One of these degradation products is acetic acid, which has corrosive properties.

### SUMMARY OF THE INVENTION

It is an object of the present invention to provide a photovoltaic module which withstands corrosive influences to which the module is subjected during its use.

It is another object of the present invention to provide a method of producing the photovoltaic module which withstands the corrosive influences.

These objects and others, which will be made more apparent herein after, are attained by a photovoltaic module covered by the patent claims appended herein below.

The photovoltaic module according to the invention comprises metallic silicon, at least one embedding material, and a corrosion inhibitor, which characterizes the photovoltaic module of the present invention.

“Embedding material” in the sense of the present invention means components of the photovoltaic module which enclose the solar cells to protect them. In other words, the solar cells are embedded in this embedding material. In particular those materials of the photovoltaic module which are in contact with the solar cells of the photovoltaic module should be understood as embedding materials.

An embedding material may be, for example, a plastic foil, in particular made of EVA. In embodiments in which the solar cells at least on one side are not embedded in a foil, but are in direct contact with the front pane or the back cover of the module, the embedding material comprises these latter components.

In particular embodiments of the present invention the corrosion inhibitor is incorporated in the photovoltaic module via the embedding material. For this purpose before the assembly of the photovoltaic modules according to the present invention the embedding material is provided with the corrosion inhibitor according to the present invention.

According to preferred embodiments the corrosion inhibitor is a gas phase inhibitor, so that in preferred production methods it can be deposited as vapor or from a gas phase onto the embedding materials. For that purpose the embedding material together with the corrosion inhibitor is placed in a gas-tight chamber, which is heated to temperatures of preferably between 100 and 200° C., further preferably 130 and 170° C., for a time period of preferably between 2 and 4 hours.

Then the corrosion inhibitor is available in the photovoltaic module for the soar cells, because case of solar irradiation due to the increased temperature vaporization of the inhibitor takes place which thereafter deposits it on the cooler components of the photovoltaic module, namely on the solar cells consisting of metallic silicon and other metallic components.

The corrosion inhibitor is adsorbed on the metallic surfaces. These surfaces are also the parts of the photovoltaic modules, which are highly sensitive to corrosion so that the favorable anticorrosive effect of the inhibitor is concentrated on the sites which are highly sensitive.

In alternative embodiments the corrosion inhibitor is directly applied on the solar cells during production. Due to the effect described herein, the vaporization and adsorption on surfaces, in each of the photovoltaic modules the same anticorrosive effect will be achieved through heat exposure as a result of solar irradiation, regardless of the production method that has been used to produce it.

Preferably, the corrosion inhibitor which is integrated in the embedding material of the photovoltaic module is a gas phase inhibitor.

In contrast to solid and liquid inhibitors the gaseous inhibitors (gas phase inhibitors) act by adsorption on the metal surfaces and thus they physically separate the aggressive medium and metal, and the anode and cathode, respectively. Inventors hypothesize that fine cracks are caused in the components of the solar cells due to the strong temperature fluctuations which affect a photovoltaic module. These cracks are optimum places for attack by corrosion promoting decomposition products of the module components. A respective protective coating cannot provide an effective protection from corrosion in the case of these embodiments, because the cracks occur after the production of the module.

A gas phase inhibitor is characterized in that it is deposited from the gas phase onto the components to be protected and thus it can also cover small cracks produced after manufacture. In the sense of the invention it is important that during the operation of the photovoltaic module the corrosion inhibitor can move into the gas phase and can deposit onto the parts to be protected. Since the aforesaid cracks are not present during the production of the module, a protective coating with a solid or liquid gas phase inhibitor would not be reasonable. Namely, the solid or liquid inhibitor would stay in place also during operation and thus it would not be possible to cover newly caused cracks.

Thus it is required that during the operation of the photovoltaic module at least at higher operation temperatures, in particular in the case of sunshine, the gas phase inhibitor at least partially changes into the gaseous state. This is also reasonable due to the fact that the affected components expand when heated and so that they provide a good target. Certainly, the effect of the corrosive substances in the module when heated is much more aggressive than in cold.

The corrosion inhibitor for use in the photovoltaic module according to the present invention is preferably an organic compound. Preferably, the corrosion inhibitor is selected from compounds having nitrogen-containing heterocyclic compounds. Particularly preferably, the corrosion inhibitor is selected from the group consisting of amines, cycloamines, cycloamines with attached hydrocarbon groups, phenyl amines, aniline, aniline with attached hydrocarbon groups, toluidines, toluidines with attached hydrocarbon groups, amides, aromatic azoles and acetylene alcohols.

Further preferably, the corrosion inhibitor may be a triazole.

It has been shown that the mentioned corrosion inhibitors are particularly suitable to form a chemical bond by chemisorption, thus by absorption on surfaces. Most preferably, the corrosion inhibitor is a benzotriazole or a tolyltriazole. It has further been shown that the mentioned inhibitors do not compromise the optical transmittance of the encapsulation materials and further that the adhesion of the embedding materials on the non-metallic components is not reduced.

In this specification the term “a corrosion inhibitor” or “one corrosion inhibitor” also encompasses mixtures of several corrosion inhibitors, in so far as these mixtures also have the preferred properties according to the present invention. But it is preferable to use only one corrosion inhibitor, because in that case the influence on the photovoltaic module can be more easily determined.

The term “a solar cell” or “one solar cell” in this specification also encompasses several solar cells.

The photovoltaic module is designed so that the corrosion inhibitor cannot migrate to outside regions of the solar module and thus protects the metallic components from corrosion during the entire lifetime of the photovoltaic module.

Preferably, the embedding foil is made from ethylene vinyl acetate, i.e. EVA.

The back cover which is on the back side of the photovoltaic module is preferably made of glass or is a foil.

The object of the present invention is further attained in a method comprising the following step of:
incorporating a corrosion inhibitor into a photovoltaic module.

The corrosion inhibitor which is incorporated into this photovoltaic module preferably corresponds to the above-described corrosion inhibitor. Preferably the method produces a photovoltaic module which corresponds to the above-described module according to the invention.

Furthermore the invention relates to a method of producing the above-described photovoltaic module, comprising in an arbitrary order the following steps of:
introducing a solar cell into a chamber, and
introducing a gas phase inhibitor into this chamber.

Preferably, the method further comprises the steps of:
heating the chamber to an elevated temperature of between 100 and 200° C., preferably of between 130 and 170° C.

Preferably, the method further comprises the step of
compensating a pressure between the interior region of the chamber and the surroundings.

Preferably, the method further comprises the step of
maintaining the chamber at the elevated temperature for a period of time of between 2 and 4 hours.

Preferably, the volume of the chamber is between 0.5 and 5 m³. The gas phase inhibitor is preferably used in an amount of at least 1 kg per m³ chamber volume.

In alternative embodiments the above-mentioned method is not applied to the solar cell but to the embedding material so that the corrosion inhibitor is provided in the photovoltaic module via the embedding material. In preferred embodiments both the solar cell and the embedding materials are provided with a corrosion inhibitor in this manner.

In alternative production methods according to the present invention the corrosion inhibitor is embedded into a master batch, which is incorporated into the embedding material. In the production of the photovoltaic module preferably a strong linkage on the molecular level between the embedding material and the metallic components of the module is formed.

In alternative production methods according to the present invention the solar cell is dipped into a solution of the corrosion inhibitor before the assembly of the module. Methods directly providing the solar cell with the corrosion inhibitor have the advantage that the corrosion inhibitor is directly applied onto a region to be protected and thus the amount of inhibitor can be reduced. Thus, these methods are particularly preferable.

### Example of the Method

This embodiment example does not limit the scope of the patent claims.

Embodiment Example of the Method for Coating of Solar Cells with Corrosion Inhibitor

In a separate dish an amount of granulate of tolyltriazole is put into a vessel. Already soldered cells (strings) are introduced into the gas space of the closed vessel. Now, the vessel is heated to an outside temperature of 140° C. under constant pressure compensation and the temperature is maintained for 3 hours. Now tolyltriazole coats the cells as well as the connected metallic components with the corrosion inhibitor and protects them from attacking media. After the residence time the vessel with the strings is cooled and the cells which are protected with the corrosion inhibitor are removed. Then they are laminated with front glass, embedding materials and back foils and electrically wired up as a module. Then the corrosion inhibitor can show its effectiveness against corrosion effects in various tests (damp heat test, temperature cycle test, combination test).

The example describes the coating of solar cells with the corrosion inhibitor tolyltriazole in a discontinuous operating manner: The solar cells which are soldered to so-called strings via connectors are stacked in a coating chamber (which is lockable in a gas-tight manner) with temperature control facilities having an inside volume of ca. 0.5 to 5 m³ in a rack system so all sides of all strings are exposed to the interior atmosphere of the chamber. Fans and air baffles in the chamber provide forced convection with a nearly homogenous incident flow of air and the gas atmosphere, respectively, to the cell surface. In an evaporation cycle at least 1 kg of granulate of tolyltriazole per m³ volume of coating chamber is introduced in a vaporization facility, which can be a heatable open vessel. Then the vaporization facility is heated to 140° C. and maintained at this temperature for 3 h. The cells may also reach this temperature, but preferably their temperature is lower than the temperature of the vaporization facility. During this time period a part of the inhibitor vaporizes and forms a homogenous vapor concentration in the atmosphere inside the chamber. A part of the vapor is absorbed on the cell surfaces and there completely covering dense layers are formed thereon. After the subsequent cooling to room temperature the adhesion of these layers on the cell surfaces is sufficient for surviving subsequent process steps of module production (transport, storage, lamination, etc.).

Principally, after the coating with the corrosion inhibitor in the coating chamber an additional (thin) preservation layer can be applied with which the inhibitor layer is protected against abrasion in subsequent (mechanical) processing steps and against dissolution in the embedding foils in the lamination step, respectively.

### BRIEF DESCRIPTION OF THE DRAWING

The objects, features and advantages of the invention will now be illustrated in more detail with the aid of the following preferred embodiments, with reference to the accompanying figures in which:

FIG. 1 is a diagrammatic cross-sectional view through a photovoltaic module of the prior art; and

FIG. 2 is a diagrammatic cross-sectional view through a corresponding preferred embodiment of the invention.

### DESCRIPTION OF THE PREFERRED EMBODIMENT

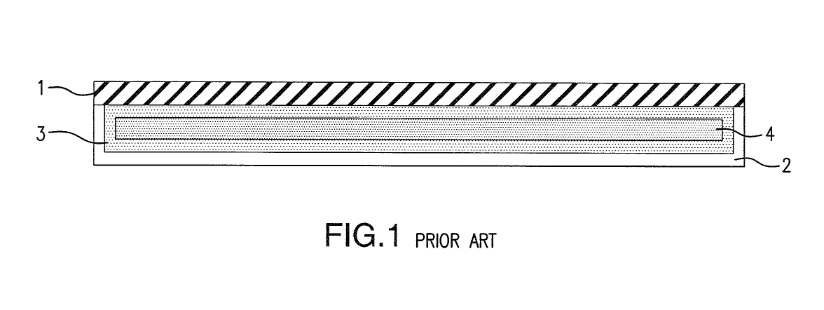

FIG. 1 shows an example of a common structure of a photovoltaic module according to the prior art, which was described in the background section herein above.

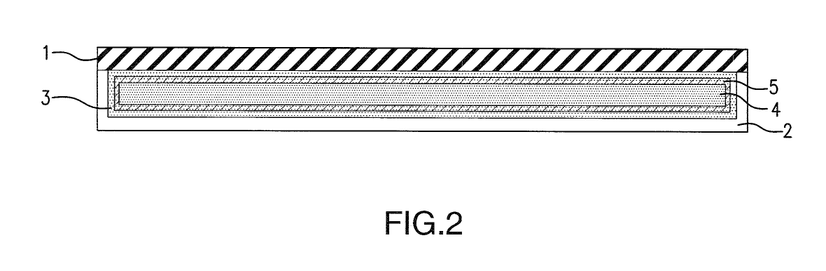

FIG. 2 shows a corresponding example of the photovoltaic module according to the invention, in which the corrosion inhibitor has been adsorbed as an inhibitor layer 5 on the surface of the solar cell 4. Otherwise the parts of the photovoltaic module according to the invention are the same as those of the module of the prior art shown in FIG. 1 and the same reference numbers are thus use for those parts in FIG. 2.

### PARTS LIST

1. Front pane
2. Back pane or back foil
3. Embedding material
4. Solar cell
5. inhibitor layer

While the invention has been illustrated and described as embodied in a photovoltaic module having improved corrosion resistance and method of producing same, it is not intended to be limited to the details shown, since various modifications and changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention.

What is claimed is new and is set forth in the following appended claims.

We claim:

1. A photovoltaic module comprising metallic silicon, at least one embedding material, and a corrosion inhibitor.

2. The photovoltaic module according to claim 1, wherein the corrosion inhibitor is a gas phase inhibitor.

3. The photovoltaic module according to claim 1, wherein the corrosion inhibitor is an organic compound.

4. The photovoltaic module according to claim 1, wherein the corrosion inhibitor is a nitrogen-containing heterocyclic compound.

5. The photovoltaic module according to claim 1, wherein the corrosion inhibitor is a benzotriazole.

6. The photovoltaic module according to claim 1, wherein the corrosion inhibitor is a tolyltriazole.

7. The photovoltaic module according to claim 1, wherein the embedding material is a plastic foil.

8. The photovoltaic module according to claim 7, wherein the plastic foil comprises ethylene vinyl acetate (EVA).

9. The photovoltaic module according to claim 1, wherein the corrosion inhibitor is adsorbed on or is absorbed in surfaces of the metallic silicon and/or other metallic components.

10. A method of producing a photovoltaic module, said method comprising the step of incorporating a corrosion inhibitor into a photovoltaic module.

11. The method according to claim 10, further comprising the steps of:
a) introducing a solar cell into a chamber;
b) introducing a gas phase inhibitor, which is at least one nitrogen-containing heterocyclic compound, into said chamber;
c) heating the chamber to an elevated temperature from 100° C. to 200° C.;
d) compensating pressure between an interior region of the chamber and surroundings of the chamber; and
e) maintaining the elevated temperature in the chamber for a period of time from 2 to 4 hours.
